(19) United States
(12) Patent Application Publication
(10) Pub. No.: US 2006/0164098 A1
(43) Pub. Date: Jul. 27, 2006

(54) Utilization of power delivered to powered device during detection and classification mode

(75) Inventor: Kirk Tzukai Su, Santa Barbara, CA (US)

Correspondence Address: MCDERMOTT WILL & EMERY LLP, 600 13TH STREET, N.W., WASHINGTON, DC, 20005-3096, US

(73) Assignee: LINEAR TECHNOLOGY CORPORATION

(21) Appl. No.: 11/325,319

(22) Filed: Jan. 5, 2006

Related U.S. Application Data
(60) Provisional application No. 60/646,509, filed on Jan. 25, 2005.

(51) Int. Cl. G01R 31/11

(52) U.S. Cl. 324/534

(57) ABSTRACT

A powered device for receiving power from a power supply device over a communication link has operation support circuitry responsive to power provided by the power supply device in a detection or classification mode to enable the power supply device to operate in the detection or classification mode, and auxiliary circuitry configured for being powered by at least a portion of the power supplied in the detection or classification mode.

This application claims priority of provisional U.S. patent application No. 60/646,509 filed on Jan. 25, 2005, and entitled “SYSTEM AND METHOD FOR SUPPORTING ADVANCED POWER OVER ETHERNET SYSTEM.”

### TECHNICAL FIELD

This disclosure relates to power supply systems, and more particularly, to circuitry and methodology for utilizing power delivered to a device powered over a communication link during detection and classification procedures.

### BACKGROUND ART

Over the years, Ethernet has become the most commonly used method for local area networking. The IEEE 802.3 group, the originator of the Ethernet standard, has developed an extension to the standard, known as IEEE 802.3af, that defines supplying power over Ethernet cabling. The IEEE 802.3af standard defines a Power over Ethernet (PoE) system that involves delivering power over unshielded twisted-pair wiring from Power Sourcing Equipment (PSE) to a Powered Device (PD) located at opposite sides of a link. Traditionally, network devices such as IP phones, wireless LAN access points, personal computers and Web cameras, have required two connections: one to a LAN and another to a power supply system. The PoE system eliminates the need for additional outlets and wiring to supply power to network devices. Instead, power is supplied over Ethernet cabling used for data transmission.

As defined in the IEEE 802.3af standard, PSE and PD are non-data entities allowing network devices to supply and draw power using the same generic cabling as is used for data transmission. A PSE is the equipment electrically specified at the point of the physical connection to the cabling, that provides the power to a link. A PSE is typically associated with an Ethernet switch, router, hub or other network switching equipment or midspan device. A PD is a device that is either drawing power or requesting power. PDs may be associated with such devices as digital IP telephones, wireless network access points, PDA or notebook computer docking stations, cell phone chargers and HVAC thermostats.

PSE's main functions are to detect a PD requesting power, optionally classify the PD, supply power to the link if a PD is detected, monitor the power on the link, and disconnect power when it is no longer requested or required. In a detection mode, a PD presents a valid or non-valid detection signature to request power. The PD detection signature has electrical characteristics measured by the PSE.

If the detection signature is valid, the PD has an option of operating in a classification mode to indicate how much power it will draw when powered up. A PD may be classified as class 0 to class 4. A PD of class 1 requires that the PSE supplies at least 4.0 W, a PD of class 2 requires that the PSE supplies at least 7.0 W, and a PD of class 0, 3 or 4 requires at least 15.4 W. Based on the determined class of the PD, the PSE applies the required power to the PD.

During the detection and classification modes, the PSE applies detection and classification voltages prescribed by the IEEE 802.3af standard to determine detection and classification signatures of the PD. It would be desirable to provide circuitry and methodology for utilizing power supplied by the PSE during the detection and classification modes to support other functions of the PD.

### SUMMARY OF THE DISCLOSURE

The present disclosure offers novel circuitry and methodology for providing power over a communication link. In accordance with one aspect of the present disclosure, a powered device for receiving power from a power supply device over a communication link includes operation support circuitry responsive to power provided by the power supply device in a detection or classification mode to enable the power supply device to operate in the detection or classification mode, and auxiliary circuitry configured for being powered by at least a portion of the power supplied in the detection or classification mode. It is noted that the power supply device may include a PSE, midspan, power injector, or any other device for supplying power.

In accordance with an embodiment of the disclosure, a powered device for receiving power from a power supply device in a Power over Ethernet system comprises classification support circuitry responsive to classification power provided by the power supply device in a classification mode to enable the power supply device to determine a power requirement of the powered device, and auxiliary circuitry configured for being powered by at least a portion of the classification power.

The powered device may include classification power supply circuitry responsive to the classification power for providing a power supply of the auxiliary circuitry. For example, the classification power supply circuitry may comprise a sample and hold circuit having a power accumulator circuit charged during the classification mode to supply the auxiliary circuitry with accumulated power.

The power accumulator circuit may include a capacitor connectable to a source of the classification power for charging during a predetermined time period. After expiration of this time period, the capacitor is disconnected from the source of the classification power to enable the classification current for a selected class to be provided.

Alternatively, a threshold detector may be provided for determining whether a classification signal provided by the powered device exceeds a threshold level required to present a valid classification signature for a particular class. The capacitor may be connected to the source of the classification power for charging when the classification signal exceeds the threshold level.

The auxiliary circuitry may include multiple auxiliary circuits having various power consumption levels. A logic circuit may be provided for selecting the auxiliary circuits that can be powered by an available classification power level.

The logic circuit may also control charging and discharging of the capacitor in the sample and hold circuit and control a classification current source to provide a classification current corresponding to the selected class.

In accordance with a method of the present disclosure, the following steps are carried out to classify a powered device in a Power over Ethernet system:

in response to power supplied from a power supply device in a classification mode, providing classification current representing a particular class of the powered device, and

supplying at least a portion of the power received in the classification mode to support operation of auxiliary circuitry.

The power supplied in the classification mode may be accumulated for a predetermined time period and used for powering the auxiliary circuitry. The classification current may be presented after the predetermined time interval.

Alternatively, when the classification current drawn by the powered device in the classification mode exceeds a threshold level required to present a valid classification signature for a particular class, the power supplied in the classification mode may be accumulated for powering the auxiliary circuitry.

In accordance with another aspect of the disclosure, a powered device for receiving power from a power supply device in a Power over Ethernet system comprises detection support circuitry responsive to detection power supplied by the power supply device in a detection mode for enabling the power supply device to detect the powered device, and auxiliary circuitry configured to be powered by at least a portion of the detection power.

The detection support circuitry may include signature resistance for providing the power supply device with a valid detection signature. Alternatively, the signature resistance may be eliminated and the auxiliary circuitry may be configured to provide a valid detection signature.

Additional advantages and aspects of the disclosure will become readily apparent to those skilled in the art from the following detailed description, wherein embodiments of the present disclosure are shown and described, simply by way of illustration of the best mode contemplated for practicing the present disclosure. As will be described, the disclosure is capable of other and different embodiments, and its several details are susceptible of modification in various obvious respects, all without departing from the spirit of the disclosure. Accordingly, the drawings and description are to be regarded as illustrative in nature, and not as limitative.

### BRIEF DESCRIPTION OF THE DRAWINGS

The following detailed description of the embodiments of the present disclosure can best be understood when read in conjunction with the following drawings, in which the features are not necessarily drawn to scale but rather are drawn as to best illustrate the pertinent features, wherein:

FIG. 1 is a diagram illustrating a Power over Ethernet system of the present disclosure.

FIG. 2 is a diagram illustrating conventional detection circuitry of a powered device (PD).

FIG. 3 is a diagram illustrating conventional classification circuitry of a PD.

FIG. 4 is a diagram illustrating detection circuitry of a PD in accordance with the present disclosure.

FIG. 5 is a diagram illustrating classification circuitry of a PD in accordance with the present disclosure.

FIG. 6 is a diagram illustrating an exemplary embodiment of the classification circuitry in accordance with the present disclosure.

### DETAILED DISCLOSURE OF THE EMBODIMENTS

The present disclosure will be made using the example of a Power over Ethernet (PoE) system. It will become apparent, however, that the concepts described herein are applicable to any system for supplying power over a communication link. For example, the system of the present disclosure may be utilized in a local area network (LAN) having a plurality of nodes, a network hub and communication cabling connecting the nodes to the network hub for providing data communications. The network hub may include a power supply device, and the communication cabling may be utilized for supplying power from the power supply device to a powered device.

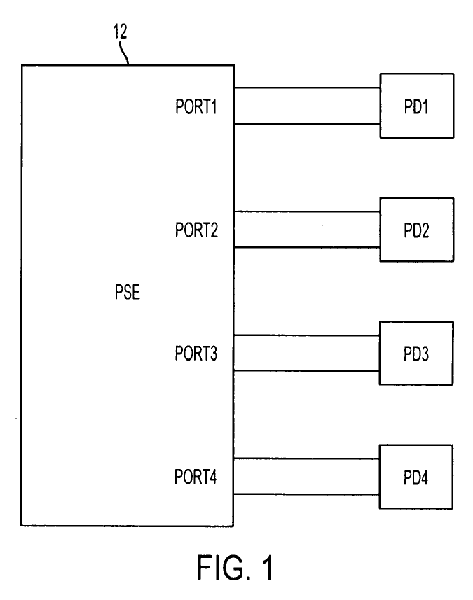

FIG. 1 shows a simplified block-diagram illustrating a PoE system 10 including Power Sourcing Equipment (PSE) 12 having multiple ports 1 to 4 connectable to Powered Devices (PD) 1 to 4 via respective links, each of which may be provided using 2 or 4 sets of twisted pairs within the Ethernet cable. Although FIG. 1 shows four ports of the PSE 12, one skilled in the art would realize that any number of ports may be provided.

The PSE 12 may interact with each PD in accordance with the IEEE 802.3af standard. In particular, the PSE 12 and the PD participate in the PD detection procedure, during which the PSE 12 probes a link to detect the PD. If the PD is detected, the PSE 12 checks the PD detection signature to determine whether it is valid or non-valid. The valid and non-valid detection signatures are defined in the IEEE 802.3af standard. While the valid PD detection signature indicates that the PD is in a state where it will accept power, the non-valid PD detection signature indicates that the PD is in a state where it will not accept power.

If the signature is valid, the PD has an option of presenting a classification signature to the PSE to indicate how much power it will draw when powered up. For example, a PD may be classified as class 0 to class 4. A PD of class 1 requires that the PSE supplies at least 4.0 W, a PD of class 2 requires that the PSE supplies at least 7.0 W, and a PD of class 0, 3 or 4 requires at least 15.4 W. Based on the determined class of the PD, the PSE applies the required power to the PD.

FIG. 2 illustrates conventional detection circuitry of the PD provided to support a detection mode in accordance with the IEEE 802.3af standard. In the detection mode, the PSE 12 produces detection voltage Vdet applied via a respective link to detect a PD connected to that link. For example, the detection voltage Vdet may be in the range from 2.7V to 10.1V. Two or more tests may be performed by the PSE to detect signature resistance of the PD. For each test, the PSE produces the detection voltage Vdet. The minimum voltage difference between the detection voltages Vdet produced for different detection tests is 1V.

Input voltage V_{IN} corresponding to the detection voltage Vdet is applied to the detection circuitry of the PD including signature resistance R1. The PSE determines current Ires produced in response to the applied detection voltage Vdet. The signature resistance R1 of the PD is determined as
R1=ΔVdet/ΔIres,
where ΔVdet is a difference between detection voltages in different tests, and ΔIres is a difference between currents produced in response to the respective detection voltages.

To be valid, the signature resistance R1 should be in a pre-defined range. For example, for a PD compliant with the IEEE 802.3af standard, the signature resistance must be in the range from 19 KOhm to 26.5 KOhm.

If the PSE determines that the signature resistance is valid, it may switch into a classification mode to determine a power requirement of the PD. FIG. 3 illustrates conventional classification circuitry of the PD provided to support the classification mode. In accordance with the IEEE 802.3af standard, in the classification mode, the PSE applies via a respective link classification voltage Vclass in the range from 14.5V to 20.5V. Input voltage V_{IN} corresponding to the classification voltage Vclass is applied to the input of the classification circuitry of the PD having a classification current source 30.

In response, the current source 30 of the classification circuitry presents classification current Iclass indicating a class of the PD. For example, in accordance with the IEEE 802.3af standard, the classification current for class 0 may be from 0 mA to 4 mA, the classification current for class 1 may be from 9 mA to 12 mA, the classification current for class 2 may be from 17 mA to 20 mA, the classification current for class 3 may be from 26 mA to 30 mA, and the classification current for class 4 may be from 36 mA to 44 mA. The PSE measures the classification current of the PD to determine its class.

Conventional detection and classification circuitries utilize power provided by the PSE in the detection and classification modes only for performing detection and classification procedures. However, it would be desirable to utilize this power for supporting other functions of the PD.

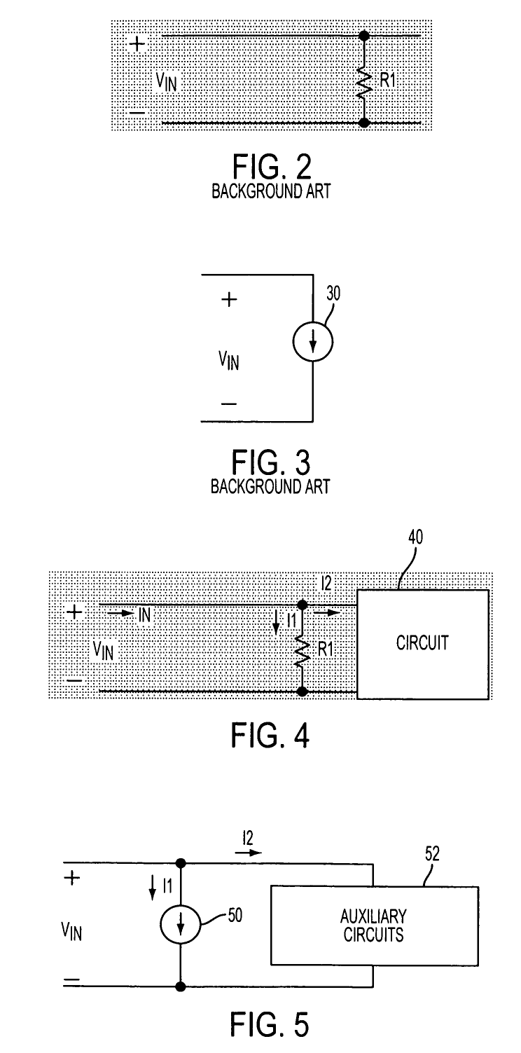

FIG. 4 illustrates detection circuitry of a PD in accordance with the present disclosure. In this circuitry, the input current I_{IN} drawn in response to the detection voltage Vdet applied by the PSE is divided into currents I1 and I2. The first current I1 supports the detection procedure, whereas the second current I2 is provided to an auxiliary circuit 40 to support its operation. For example, the circuit 40 may be micro-power digital circuitry or low-power circuitry for providing reference and supporting functions. The circuit 40 may be integrated into the PD or provided externally with respect to the PD. The input impedance of the circuit 40 is selected with respect to the value of the signature resistor R1 so as to provide current I1 sufficient for supporting the detection procedure.

Alternatively, the signature resistor may be eliminated to allow the entire value of the detection power to be delivered to the auxiliary circuit 40. In this case, the input impedance of the auxiliary circuit is selected to provide a detection signature value prescribed by the IEEE 802.3af detection signature requirement.

FIG. 5 illustrates classification circuitry of a PD in accordance with the present disclosure. In this circuitry, the classification current source 50 is connected to auxiliary circuits 52 so as to divide the classification current into current I1 used for providing a classification procedure and I2 supplied to the auxiliary circuitry 52 to support their operations. The circuitry 52 may be integrated into the PD or provided externally with respect to the PD. The current I1 is maintained at a level sufficient to present at least minimum prescribed classification current for a selected class. For example, to operate in accordance with the IEEE 802.3af standard-complying classification procedure, the current I1 should be at least 9 mA for class 1, 17 mA for class 2, 26 mA for class 3 and 36 mA for class 4. For class 0, the entire value of the classification current may be supplied to the auxiliary circuitry 52.

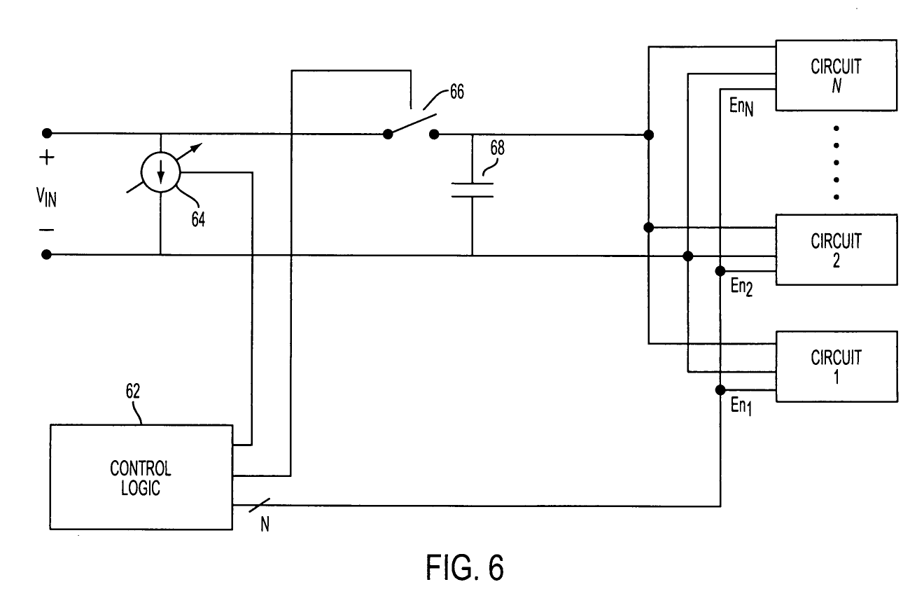

FIG. 6 shows an exemplary embodiment of the classification circuitry of a PD in accordance with the present disclosure. The classification circuitry enabled to supply at least a portion of classification power to any of n auxiliary circuits 1, 2, . . . , N having various power consumption levels includes a control logic circuit 62 for controlling classification operations, a controllable classification current source 64 for providing classification current for a selected class of the PD, and a sample and hold circuit including a switch 66 and a capacitor 68. For example, a MOSFET may be used as the switch 66. The auxiliary circuits may be integrated into the PD or provided externally with respect to the PD.

At the beginning of the classification procedure, input voltage V_{IN} is applied to the classification circuit in response to classification voltage Vclass supplied from the respective PSE. The control logic circuit 62 pre-programmed to select a class of the PD controls the controllable classification current source 64 to provide classification current corresponding to the selected class.

When the input voltage V_{IN} is applied to the classification circuit, the control logic circuit 62 may control the switch 66 to apply the input voltage V_{IN} to the capacitor 68 in order to charge the capacitor 68. For example, in accordance with the IEEE 802.3af standard, the PD has 5 ms to provide a stable classification signature. Therefore, when the input voltage V_{IN} is applied, the control logic 62 may charge the capacitor 68 for 4 ms and then disconnect the capacitor 68 from the input voltage V_{IN} to enable the classification current source 64 to provide a stable classification signature.

When the capacitor 68 is disconnected from the classification power source, the accumulated charge may be used to provide power to the auxiliary circuits 1, 2, . . . , N connected to the capacitor 68. Based on the selected class and the respective value of the classification current, the control logic circuit 62 may select auxiliary circuits that can be powered by the available classification power. An n-wired enabling bus En may be provided between the control logic circuit 62 and the n auxiliary circuits 1, 2, . . . , N to enable the selected auxiliary circuits to receive power from the capacitor 68. For example, the auxiliary circuits may provide the PD with a memory function for maintaining information when power is removed from the PD for a limited amount of time.

Alternatively, at the beginning of the classification procedure, the capacitor 68 may be disconnected from the classification power source. The control logic circuit 62 may contain a threshold detector that determines when the current drawn by the PD during the classification procedure exceeds a threshold level required for presenting a classification signature for a selected class. When the drawn current exceeds the threshold level that may correspond to the minimum classification current required for a selected class, the control logic circuit 62 controls the switch 66 to connect the capacitor 68 to the input voltage V_{IN} to charge this capacitor from the classification power source. The accumulated charge may be used to power the auxiliary circuits selected by the control logic circuit 62.

The foregoing description illustrates and describes aspects of the present invention. Additionally, the disclosure shows and describes only preferred embodiments, but as aforementioned, it is to be understood that the invention is capable of use in various other combinations, modifications, and environments and is capable of changes or modifications within the scope of the inventive concept as expressed herein, commensurate with the above teachings, and/or the skill or knowledge of the relevant art.

The embodiments described hereinabove are further intended to explain best modes known of practicing the invention and to enable others skilled in the art to utilize the invention in such, or other, embodiments and with the various modifications required by the particular applications or uses of the invention.

Accordingly, the description is not intended to limit the invention to the form disclosed herein. Also, it is intended that the appended claims be construed to include alternative embodiments.

What is claimed is:

1. A powered device for receiving power supplied from a power supply device over a communication link, comprising:
operation support circuitry responsive to power provided by the power supply device in a detection or classification mode to enable the power supply device to operate in the detection or classification mode, and
auxiliary circuitry configured for being powered by at least a portion of the power supplied in the detection or classification mode.

2. A powered device for receiving power from a power supply device in a Power over Ethernet (PoE) system, comprising:
classification support circuitry responsive to classification power provided by the power supply device in a classification mode to enable the power supply device to determine a power requirement of the powered device, and
auxiliary circuitry configured for being powered by at least a portion of the classification power.

3. The device of claim 2, further comprising classification power supply circuitry responsive to the classification power for providing a power supply of the auxiliary circuitry.

4. The device of claim 3, wherein the classification power supply circuitry comprises a sample and hold circuit.

5. The device of claim 4, wherein the sample and hold circuit comprises a power accumulator circuit charged during the classification mode to supply the auxiliary circuitry with accumulated power.

6. The device of claim 5, wherein the power accumulator circuit includes a capacitor connectable to a source of the classification power for charging during a predetermined time period.

7. The device of claim 5, wherein the classification power supply circuitry includes a threshold detector for determining whether a classification signal exceeds a threshold level required by the powered device to operate in the classification mode.

8. The device of claim 7, wherein the sample and hold circuit includes a capacitor connectable to a source of the classification power for charging when the classification signal exceeds the threshold level.

9. The device of claim 4, wherein the auxiliary circuitry includes multiple auxiliary circuits having various power consumption levels.

10. The device of claim 9, wherein the classification power supply circuitry includes logic circuitry for controlling the sample and hold circuit.

11. The device of claim 10, wherein the logic circuit is configured for selecting the auxiliary circuits to be powered by available classification power.

12. The device of claim 11, wherein the classification support circuitry comprises a controllable classification current source for providing a classification current corresponding to the power requirement of the powered device.

13. The device of claim 12, wherein the logic circuit is configured for controlling the controllable classification current source.

14. A powered device for receiving power from a power supply device in a Power over Ethernet system, comprising:
detection support circuitry responsive to detection power supplied by the power supply device in a detection mode for enabling the power supply device to detect the powered device, and
auxiliary circuitry configured for being powered by at least a portion of the detection power.

15. The device of claim 14, wherein the detection support circuitry includes signature resistance for providing the power supply device with a valid detection signature.

16. The device of claim 14, wherein the auxiliary circuitry is configured to provide a valid detection signature.

17. A method of classifying a powered device in a Power over Ethernet system, comprising the steps of:
in response to power supplied from a power supply device in a classification mode, providing classification current representing a particular class of the powered device, and
supplying at least a portion of the power received in the classification mode to support operation of auxiliary circuitry.

18. The method of claim 17, wherein the power supplied in the classification mode is accumulated for a predetermined time period.

19. The method of claim 18, wherein the classification current is presented after the predetermined time interval.

20. The method of claim 17, further comprising the step of determining when the classification current drawn by the powered device in the classification mode exceeds a threshold level required to present the particular class of the powered device.

21. The method of claim 20, wherein the power supplied in the classification mode is accumulated for powering the auxiliary circuitry when the classification current exceeds the threshold level.
